(19) United States
(12) Patent Application Publication
(10) Pub. No.: US 2009/0085075 A1
(43) Pub. Date: Apr. 2, 2009

(54) METHOD OF FABRICATING MOS TRANSISTOR AND MOS TRANSISTOR FABRICATED THEREBY

(75) Inventors: Ki-chul KIM, Suwon-si (KR); Hong-Jae Shin, Seoul (KR); Jung-Deog Lee, Yongin-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/196,454

(22) Filed: Aug. 22, 2008

(30) Foreign Application Priority Data
Aug. 24, 2007 (KR) 2007-85456

(51) Int. Cl. H01L 29/78; H01L 21/3205; H01L 21/8238

(52) U.S. Cl. 257/288; 438/596; 438/230; 257/E29.255; 257/E21.409; 257/E21.158

(57) ABSTRACT

A method of fabricating a MOS transistor, and a MOS transistor fabricated by the method. The method can include forming a gate pattern on a semiconductor substrate. The gate pattern can be formed by sequentially stacking a gate electrode and a capping layer pattern. The capping layer pattern is formed to have a lower capping layer pattern and an upper capping layer pattern. The lower capping layer pattern is formed to a smaller width than the upper capping layer pattern.

### CROSS-REFERENCE TO RELATED APPLICATIONS

This application claims the benefit of Korean Patent Application No. 2007-85456, filed Aug. 24, 2007, the contents of which are hereby incorporated herein by reference in their entirety.

### BACKGROUND OF THE INVENTION

1. Field of the Invention

The present general inventive concept relates to a method of fabricating a semiconductor device and a semiconductor device fabricated thereby, and, more particularly, to a method of fabricating a MOS transistor and a MOS transistor fabricated thereby.

2. Description of the Related Art

Owing to the increased demand for highly integrated, high-speed semiconductor devices, a vast amount of research has been conducted on various methods for overcoming restrictions caused by the downscaling of the semiconductor devices.

### SUMMARY OF THE INVENTION

The present general inventive concept provides a method of fabricating a MOS transistor, which can prevent occurrence of a short circuit between a gate pattern and adjacent conductive layers to improve the reliability of a semiconductor device.

The present general inventive concept also provides a method of fabricating an interconnection structure of a semiconductor device, which can prevent occurrence of a short circuit between a gate pattern and adjacent conductive layers to improve the reliability of the semiconductor device.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept may be achieved by providing a method of fabricating a MOS transistor including forming a gate pattern on a semiconductor substrate. The gate pattern is formed by sequentially stacking a gate electrode and a capping layer pattern. The capping layer pattern is formed by sequentially stacking a lower capping layer pattern and an upper capping layer pattern. The lower capping layer pattern is formed to a smaller width than the upper capping layer pattern. A spacer is formed to cover a sidewall of the gate pattern.

In some example embodiments of the present general inventive concept, the lower capping layer pattern may include a material layer having an etch selectivity with respect to the gate electrode and the upper capping layer pattern. The lower capping layer pattern may be formed to a smaller width than the gate electrode. The lower capping layer pattern may be formed to be more oxidative than the gate electrode and the upper capping layer pattern. The upper capping layer pattern may include an insulating material, and the lower capping layer pattern may include a conductive layer or an insulating layer. The lower capping layer pattern may include a germanium (Ge) layer or a silicon germanium (SiGe) layer.

The formation of the gate pattern may include sequentially stacking a gate electrode layer, a lower capping layer, and an upper capping layer on the semiconductor substrate. The upper and lower capping layers may be sequentially patterned to form the upper capping layer pattern and a preliminary lower capping layer pattern. Sidewalls of the preliminary lower capping layer pattern may be etched to form the lower capping layer pattern. The gate electrode layer may be etched to form the gate electrode.

In another example embodiment, the formation of the gate pattern may include sequentially stacking a gate electrode layer, a lower capping layer, and an upper capping layer on the semiconductor substrate. Thereafter, the upper capping layer, the lower capping layer, and the gate electrode layer may be sequentially patterned to form the upper capping layer pattern, a preliminary lower capping layer pattern, and the gate electrode. The preliminary lower capping layer pattern may be etched to form the lower capping layer pattern.

The etching of the preliminary lower capping layer pattern may be performed by an isotropic etching process using a mixture of NH₃OH, H₂O₂, and water as an etchant.

In other example embodiments, the spacer may be integrally formed and partially interposed between the upper capping layer pattern and the gate electrode.

In yet other example embodiments, the method may further include forming an outer spacer to cover the spacer. The spacer may be interposed between the upper capping layer pattern and the gate electrode. The spacer may include an oxide layer, and the outer spacer may include a silicon nitride layer.

In yet other example embodiments, the method may further include etching portions of the semiconductor substrate at both sides of the gate pattern using the spacer and the gate pattern as an etch mask to form a recess region, and forming a semiconductor layer to fill the recess region. The semiconductor layer may be formed using an epitaxial growth technique.

The semiconductor layer may be formed of a semiconductor material to apply stress to a channel region disposed under the gate pattern. Also, the semiconductor layer may include a semiconductor material containing Ge or carbon (C).

The method may further include doping impurity ions into the semiconductor layer. The doped impurity ions may be activated to form source and drain regions in the semiconductor layer. In this case, the source and drain regions may extend from the semiconductor layer to the semiconductor substrate.

The foregoing and/or other aspects and utilities of the present general inventive concept may also be achieved by providing a MOS transistor including a gate pattern including a gate electrode and a capping layer pattern that are stacked sequentially on a semiconductor substrate. The capping layer pattern includes a lower capping layer pattern and an upper capping layer pattern that are sequentially stacked. The lower capping layer pattern has a smaller width than the upper capping layer. A spacer covers a sidewall of the gate pattern.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIGS. 1 through 7 are cross-sectional views illustrating methods of fabricating a MOS transistor according to exemplary embodiments of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

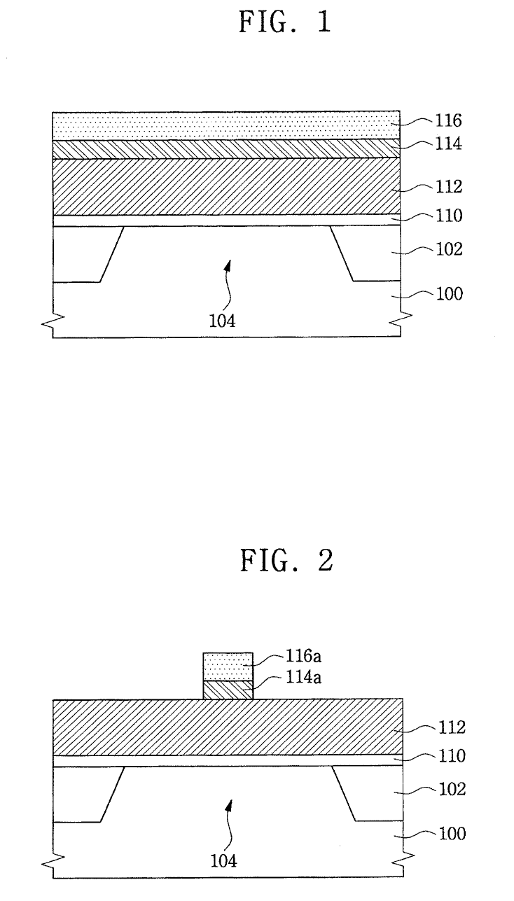

Hereinafter, methods of fabricating a MOS transistor according to exemplary embodiments will be described with reference to FIGS. 1 through 7. A method of fabricating an interconnection structure according to exemplary embodiments of the present general inventive concept can be applied to all semiconductor devices having interconnection structures, for example, dynamic random access memory (DRAM) devices, flash memory devices, static random access memory (SRAM) devices, or phase-change random access memory (PRAM) devices.

Referring to FIG. 1, a device isolation layer 102 may be formed on a semiconductor substrate 100 to define an active region 104. The semiconductor substrate 100 may be a single crystalline semiconductor substrate or a silicon-on-insulator (SOI) substrate having a single crystalline semiconductor body layer. The single crystalline semiconductor substrate or the single crystalline semiconductor body layer may include a Si layer, a Ge layer, or a SiGe layer. The device isolation layer 102 may be obtained using a shallow trench isolation (STI) technique.

Thereafter, a gate dielectric layer 110, a gate electrode layer 112, a lower capping layer 114, and an upper capping layer 116 may be sequentially formed on the semiconductor substrate 100 having the active region 104. The gate dielectric layer 110 may be a thermal oxide layer or a high-k dielectric layer. The gate electrode layer 112 may be a silicon layer, for example, a doped polysilicon (poly-Si) layer. The upper capping layer 116 may be a material layer having an etch selectivity with respect to the gate electrode layer 112, for example, a silicon nitride layer. The lower capping layer 114 may be a conductive layer or an insulating layer, which has an etch selectivity with respect to the upper capping layer 116. Also, the lower capping layer 114 may be a material layer that is more oxidative than the gate electrode layer 112 and the upper capping layer 116. In order to satisfy the above-described conditions, the lower capping layer 114 may comprise a Ge-containing material layer. Specifically, the lower capping layer 114 may comprise a Ge layer or a SiGe layer.

Referring to FIG. 2, the upper capping layer 116 and the lower capping layer 114 are sequentially patterned, thereby forming a preliminary lower capping layer pattern 114a and an upper capping layer pattern 116a that are sequentially stacked on the gate electrode layer 112. The patterning of the upper and lower capping layers 116 and 114 may include forming a photoresist pattern on the upper capping layer 116 and sequentially dry etching the upper and lower capping layers 116 and 114 using the photoresist pattern as an etch mask. After the patterning process is finished, the photoresist pattern may be removed. The dry etching of the upper and lower capping layers 116 and 114 may be performed using a plasma reactive ion etching technique. In this case, the preliminary lower capping layer pattern 114a may be formed to substantially the same width as the upper capping layer pattern 116a.

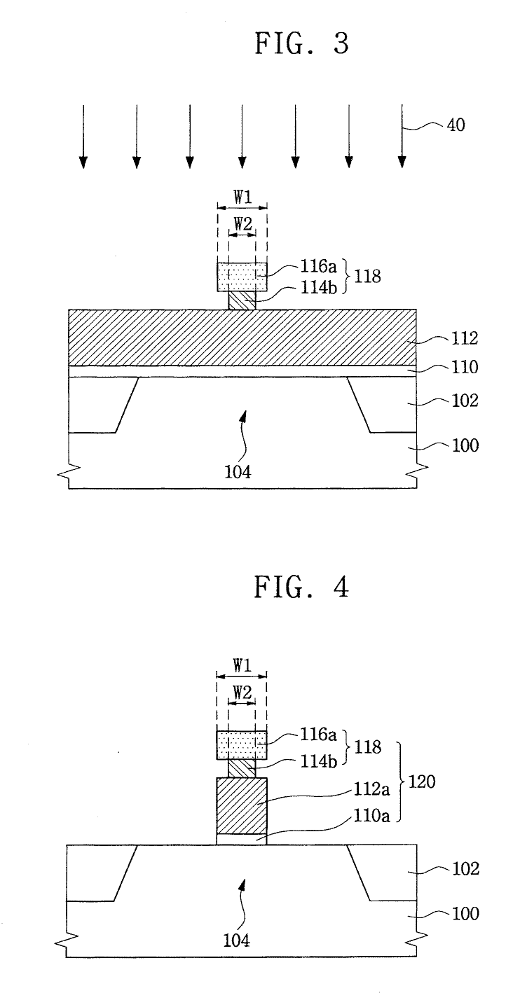

Referring to FIG. 3, an etching process may be performed on sidewalls of the preliminary lower capping layer pattern 114a. The etching process may be an isotropic etching process. For example, the isotropic etching process may be a wet etching process using a mixture of NH₃OH, H₂O₂, and water as an etchant 40. The etchant 40 may be used to selectively etch the sidewalls of the preliminary lower capping layer pattern 114a with respect to the upper capping layer pattern 116a, thereby forming a lower capping layer pattern 114b. As a result, the lower capping layer pattern 114b may have a width W2 smaller than a width W1 of the upper capping layer pattern 116a. Thus, the lower and upper capping layer patterns 114b and 116a that are stacked sequentially may constitute a capping layer pattern 118. In the present example embodiment, the capping layer patterns 118 are formed to have separate lower and upper patterns. However, the present general inventive concept is not limited thereto, and the capping layer pattern 118 may alternatively be integrally formed. In this case, a lower region of the capping layer pattern 118 may be formed to a smaller width than the width of an upper region thereof.

Referring to FIG. 4, the gate electrode layer 112 and the gate dielectric layer 110 (of FIG. 3) may be sequentially etched using the capping layer pattern 118 as an etch mask. Thus, a gate pattern 120 including a gate dielectric layer pattern 110a, a gate electrode 112a, and the capping layer pattern 118 that are stacked sequentially is formed. The lower capping layer pattern 114b may have a smaller width than the gate electrode 112a. Also, when the lower capping layer pattern 114b is formed of a conductive layer, the lower capping layer pattern 114b may be an upper gate electrode.

In the exemplary embodiment described with reference to FIGS. 2 through 4, the lower capping layer pattern 114b is formed before the gate electrode 112a. However, in another exemplary embodiment, the upper capping layer 116, the lower capping layer 114, and the gate electrode layer 112 may be sequentially patterned, thereby forming the upper capping layer pattern 116a, the preliminary lower capping layer pattern 114a, and the gate electrode 112a. In this case, the gate electrode 112a may be formed to have a uniform sidewall profile. Thereafter, the preliminary lower capping layer pattern 114a may be etched to form the lower capping layer pattern 114b. The etching of the preliminary lower capping layer pattern 114a may be performed using substantially the same method as described with reference to FIG. 3.

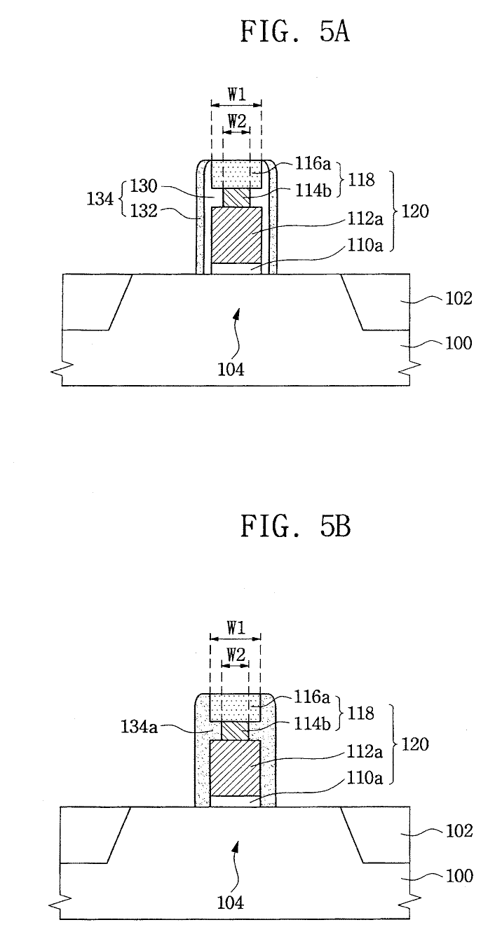

Referring to FIG. 5A, inner spacers 130 may be formed between the upper capping layer pattern 116a and the gate electrode 112a. The inner spacers 130 may extend to sidewalls of the gate electrode 112a and sidewalls of the upper capping layer patterns 116a. Meanwhile, the inner spacers 130 may include an oxide layer. For example, the inner spacer 130 may be formed of a thermal oxide layer. When the lower capping layer pattern 114b is formed of a Ge layer or a SiGe layer, the thermal oxide layer may be grown to be thicker than the other patterns 112a and 116a. As described above, this is because the lower capping layer pattern 114b is more oxidative than the adjacent other patterns 112a and 116a. Thus, the inner spacers 130 may be formed to have vertical sidewall profiles by controlling a process temperature during a thermal oxidation process. As a result, even if the upper capping layer pattern 116a is etched during the etching of the gate electrode layer 112 and left to a smaller width than the gate electrode 112a, the sidewall profiles of the inner spacers 130 are not affected by adjacent patterns.

Subsequently, an outer spacer layer may be deposited on the entire surface of the semiconductor substrate 100 along sidewalls of the gate pattern 120 and the inner spacers 130. The outer spacer layer may include a silicon nitride layer. Thereafter, the outer spacer layer may be anisotropically etched, thereby forming outer spacers 132 on the sidewalls of the inner spacers 130. Since the outer spacers 132 are formed along the sidewall profiles of the inner spacers 130, the outer spacers 132 also may have vertical sidewall profiles. As a result, spacers 134 including the inner spacers 130 and the outer spacers 132 may be formed. Also, the spacers 134 may be formed to have vertical sidewall profiles without protrusions.

In the present exemplary embodiment, it is described that each of the spacers 134 can include a plurality of spacers (i.e., the inner spacer 130 and the outer spacer 132). However, in another exemplary embodiment as illustrated in FIG. 5B, a spacer 134a may be integrally formed (i.e., one integral material formation) and partially interposed between the upper capping layer pattern 116a and the gate electrode 112a. The spacer 134a may include a silicon nitride layer.

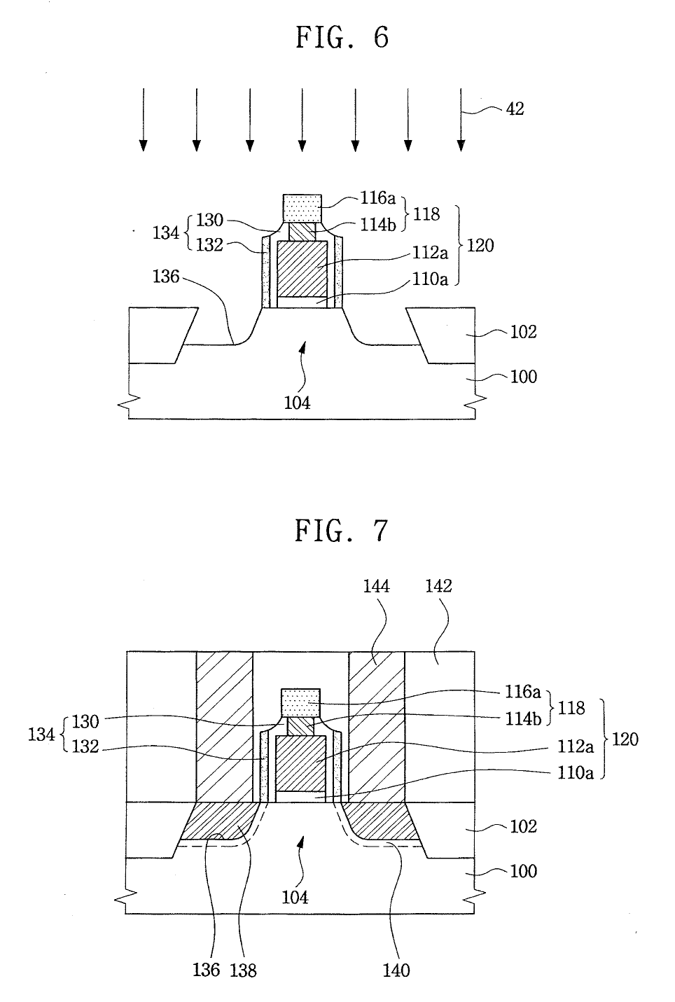

Referring to FIG. 6, portions of the semiconductor substrate 100 disposed at both sides of the gate pattern 120 are etched using the gate pattern 120 and the device isolation layer 102 as an etch mask. In other words, the portions of the semiconductor substrate 100 disposed at both sides of a channel region disposed under the gate pattern 120 are etched. The etching process may be a dry etching process using a chlorine gas 42 as a source gas. However, other types of etching processes may alternatively be used which provide the intended purpose as described herein. As a result, recess regions 136 are formed at both sides of the channel region. In this case, even if the upper capping layer pattern 116a is recessed, only the inner spacers 130 disposed under the upper capping layer pattern 116a are exposed such that the gate electrode 112a and the lower capping layer pattern are not exposed. In other words, a margin of the etching process can be ensured by etching the inner spacers 130. Furthermore, since the spacers 134 have the vertical sidewall profiles as described above, upper portions of the spacers 134 are etched before other portions thereof. Thus, an upper edge of the gate electrode 112a and the lower capping layer pattern are not exposed. In other words, the upper portions of the spacers 134 are etched first because there are no protrusions on sidewalls of the spacers 134.

Referring to FIG. 7, semiconductor layers 138 may be formed to fill the recess regions 136. The semiconductor layer 138 may be a semiconductor material layer that applies stress to the channel region disposed under the gate pattern 120. The semiconductor layers 138 may include a Ge-containing material. For instance, the semiconductor layers 138 may be obtained by epitaxially growing a semiconductor material layer, such as a SiGe layer or a Ge layer, on the recess regions 136. In this case, the gate electrode 112a and the lower capping layer pattern 114b are not exposed due to the spacers 134 so that the epitaxially grown semiconductor material layer is not formed on the gate electrode 112a and the lower capping layer pattern 114b. Thus, an electric short does not occur between the gate electrode 112a and the semiconductor layers 138.

Meanwhile, when the semiconductor layers 138 are formed of a Ge-containing semiconductor material, the semiconductor layers 138 may apply a compressive stress to the channel region. As a result, when a PMOS transistor is formed on the active region 104, the hole mobility of the PMOS transistor can be improved. In another example embodiment, when the semiconductor layers 138 may include a C-containing semiconductor material, such as silicon carbide (SiC), the semiconductor layers 138 may apply tensile stress to the channel region. As a result, when an NMOS transistor is formed on the active region 104, the electron mobility of the NMOS transistor can be improved.

Thereafter, impurity ions may be doped into the semiconductor layers 138. The impurity ions may be of an n conductivity type or a p conductivity type. The doped impurity ions may be activated. As a result, source and drain regions 140 may be formed in the semiconductor layers 138. Furthermore, the source and drain regions 140 may form junctions at interfaces between the semiconductor layers 138 and the semiconductor substrate 100. In another example embodiment, the source and drain regions 140 may form junctions in regions that extend from the semiconductor layers 138 to the semiconductor substrate 100, and enclose the semiconductor layers 138. In the above-described process, a MOS transistor having a strained channel may be completed.

Although not illustrated in the drawings, a metal silicide layer may be formed on the surfaces of the source and drain regions 140. Also, a self-align silicide (salicide) process to form a metal silicide layer may be performed not only on the surfaces of the source and drain regions 140, but also on the gate electrode 112a. In order to carry out the salicide process, the capping layer pattern 118 may be selectively removed. In another case, when the lower capping layer pattern 114b may be formed of a Ge layer or a SiGe layer, the upper capping layer pattern 116a may be selectively removed and the salicide process may be performed on the lower capping layer pattern 114b.

An interlayer insulating layer 142 may be formed on the semiconductor substrate 100 having the source and drain regions 140. The interlayer insulating layer 142 may be formed of a silicon oxide layer. Contact structures 144 may be formed through the interlayer insulating layer 142 and electrically connected to the source and drain regions 140. In the present exemplary embodiment, the spacers 134 may be partially interposed between the upper capping layer pattern 116a and the gate electrode 112a, and the lower capping layer pattern 114b may have a smaller width than the gate electrode 112a and the upper capping layer pattern 116a so that the spacers 134 can prevent the gate electrode 112a and the lower capping layer pattern 114b from being exposed during the formation of the recess regions 136 and/or the contact structures. Thus, an excessive semiconductor layer is not formed on the gate electrode 112, thereby preventing the occurrence of a short between the gate electrode 112a and the adjacent contact structure 144. As stated above, a short between the gate electrode 112a and the source and drain regions 140 can be prevented from occurring. Therefore, the reliability of the MOS transistor can be enhanced.

Hereinafter, a MOS transistor according to another example embodiment of the present general inventive concept will be described with reference to FIG. 7.

Referring to FIG. 7, a device isolation layer 102 may be provided on a semiconductor substrate 100 to define an active region 104. A gate pattern 120 is disposed on the active region 104. The gate pattern 120 may include a gate dielectric layer pattern 110a, a gate electrode 112a, and a capping layer pattern 118 that are stacked sequentially. The gate electrode 112a may include a silicon layer, for example, a doped poly-Si layer.

The capping layer pattern 118 may include a lower capping layer pattern 114b and an upper capping layer pattern 116a that are stacked sequentially. The lower capping layer pattern 114b has a smaller width than the upper capping layer pattern 116a. Also, the lower capping layer pattern 114b has a smaller width than the gate electrode 112a. The upper capping layer pattern 116a may be formed of a material layer having an etch selectivity with respect to the gate electrode 112a, for example, a silicon nitride layer. The lower capping layer pattern 114b may be formed of a conductive layer or an insulating layer, which has an etch selectivity with respect to the gate electrode 112a and the upper capping layer pattern 116a. Furthermore, the lower capping layer pattern 114b may be formed of a material layer that is more oxidative than the gate electrode 112a and the upper capping layer pattern 116a. In order to satisfy the above-described conditions, the lower capping layer pattern 114b may be formed of a Ge-containing material layer. Specifically, the lower capping layer pattern 114b may be formed of a Ge layer or a SiGe layer. In the present exemplary embodiment, it is described that the capping layer pattern 118 has separate lower and upper patterns. However, the present general inventive concept is not limited thereto, and the capping layer pattern 118 may be integrally provided. In this case, an upper region of the capping layer pattern 118 has a smaller width than a lower region thereof.

Spacers 134 are disposed along sidewalls of the gate pattern 120. The spacers 134 may include inner spacers 130 and outer spacers 132. The inner spacers 130 are interposed between the upper capping layer pattern 116a and the gate electrode 112a, and the outer spacers 132 cover the inner spacers 130. The inner spacers 130 may extend to sidewalls of the gate electrode 112a and sidewalls of the upper capping layer pattern 116a. Meanwhile, the inner spacers 130 may be formed of an oxide layer. For example, the inner spacers 130 may be formed of a thermal oxide layer. When the lower capping layer pattern 114b is formed of a Ge layer or a SiGe layer, the thermal oxide layer may be grown to be thicker than the other patterns 112a and 116a. As described above, this is because the lower capping layer pattern 114b is more oxidative than the adjacent other patterns 112a and 116a. Thus, the inner spacers 130 can have vertical sidewall profiles by controlling a process temperature during a thermal oxidation process. Also, the outer spacers 132 may include a silicon nitride layer. Furthermore, since the outer spacers 132 are disposed along the sidewall profiles of the inner spacers 130, the outer spacers 132 also may have vertical sidewall profiles. As a result, spacers 134 may be formed to have vertical sidewall profiles without protrusions.

Meanwhile, semiconductor layers 138 are disposed at both sides of a channel region disposed under the gate pattern 120. The semiconductor layers 138 may be semiconductor material layers that apply stress to the channel region. When the semiconductor layers 138 are Ge-containing semiconductor material layers, the semiconductor layers 138 may apply a compressive stress to the channel region. As a result, when a PMOS transistor is disposed on the active region 104, the hole mobility of the PMOS transistor can be improved. In another exemplary embodiment, when the semiconductor layers 138 may be C-containing semiconductor material layers, such as silicon carbide (SiC) layers, the semiconductor layers 138 may apply tensile stress to the channel region. As a result, when an NMOS transistor is formed on the active region 104, the electron mobility of the NMOS transistor can be improved.

Source and drain regions 140 may be disposed in the semiconductor layers 138. The source and drain regions 140 may be doped with n-type or p-type impurity ions. Junctions of the source and drain regions 140 may be disposed at interfaces between the semiconductor layers 138 and the active region 104 or in regions that extend from the semiconductor layers 138 to the active region 104. The above-described components constitute a MOS transistor having a strained channel.

An interlayer insulating layer 142 may be disposed on the semiconductor substrate 100 having the source and drain regions 140. The interlayer insulating layer 142 may include a silicon oxide layer. Contact structures 144 may be disposed through the interlayer insulating layer 142 and electrically connected to the source and drain regions 140.

According to the embodiments of the present general inventive concept as described above, a capping layer pattern is formed on a gate electrode such that a lower region of the capping layer pattern has a smaller width than an upper region thereof. Thus, spacers, which are formed on sidewalls of a gate pattern including the capping layer pattern and the gate electrode, are interposed between the upper region of the capping layer pattern and the gate electrode. As a result, even if the capping layer pattern and the spacers are recessed during the etching of portions of a semiconductor substrate disposed at both sides of a channel region under the gate pattern, the spacers disposed adjacent to the lower region of the capping layer pattern can prevent the gate electrode from being exposed. Therefore, a semiconductor layer may not be grown on the gate electrode. In addition, a contact structure can be prevented from contacting the gate electrode. As a consequence, the reliability of a MOS transistor having a strained channel can be ensured.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of fabricating a MOS transistor, comprising:
forming a gate pattern on a semiconductor substrate, wherein the gate pattern includes a gate electrode and a capping layer pattern that are stacked sequentially, wherein the capping layer pattern includes a lower capping layer pattern and an upper capping layer pattern that are stacked sequentially, and the lower capping layer pattern is formed to a smaller width than the upper capping layer pattern; and
forming a spacer to cover a sidewall of the gate pattern.

2. The method according to claim 1, wherein the lower capping layer pattern comprises a material layer having an etch selectivity with respect to the gate electrode and the upper capping layer pattern.

3. The method according to claim 1, wherein the lower capping layer pattern is formed to a smaller width than the gate electrode.

4. The method according to claim 1, wherein the lower capping layer pattern is formed to be more oxidative than the gate electrode and the upper capping layer pattern.

5. The method according to claim 1, wherein the upper capping layer pattern comprises an insulating material, and the lower capping layer pattern comprises a germanium (Ge) layer or a silicon germanium (SiGe) layer.

6. The method according to claim 1, wherein the lower capping layer pattern comprises a conductive layer or an insulating layer.

7. The method according to claim 1, wherein forming the gate pattern includes:
sequentially stacking a gate electrode layer, a lower capping layer, and an upper capping layer on the semiconductor substrate;
sequentially patterning the upper and lower capping layers to form the upper capping layer pattern and a preliminary lower capping layer pattern;
etching sidewalls of the preliminary lower capping layer pattern to form the lower capping layer pattern; and
etching the gate electrode layer to form the gate electrode.

8. The method according to claim 7, wherein etching the preliminary lower capping layer pattern is performed by an isotropic etching process using a mixture of NH₃OH, H₂O₂, and water as an etchant.

9. The method according to claim 1, wherein forming the gate pattern includes:
sequentially stacking a gate electrode layer, a lower capping layer, and an upper capping layer on the semiconductor substrate;
sequentially patterning the upper capping layer, the lower capping layer, and the gate electrode layer to form the upper capping layer pattern, a preliminary lower capping layer pattern, and the gate electrode; and
etching the preliminary lower capping layer pattern to form the lower capping layer pattern.

10. The method according to claim 1, wherein the spacer is integrally formed and partially interposed between the upper capping layer pattern and the gate electrode.

11. The method according to claim 1, further comprising:
forming an outer spacer to cover the spacer.

12. The method according to claim 11, wherein the spacer comprises an oxide layer, and the outer spacer comprises a silicon nitride layer.

13. The method according to claim 1, further comprising:
etching portions of the semiconductor substrate at both sides of the gate pattern using the spacer and the gate pattern as an etch mask to form a recess region; and
forming a semiconductor layer to fill the recess region.

14. The method according to claim 13, wherein the semiconductor layer is formed using an epitaxial growth technique.

15. The method according to claim 13, wherein the semiconductor layer is formed of a semiconductor material to apply stress to a channel region disposed under the gate pattern.

16. The method according to claim 13, wherein the semiconductor layer comprises a semiconductor material containing Ge or carbon (C).

17. The method according to claim 13, further comprising:
doping impurity ions into the semiconductor layer; and
activating the doped impurity ions to form source and drain regions in the semiconductor layer,
wherein the source and drain regions extend from the semiconductor layer to the semiconductor substrate.

18. A MOS transistor comprising:
a gate pattern including a gate electrode and a capping layer pattern that are sequentially stacked on a semiconductor substrate, wherein the capping layer pattern includes a lower capping layer pattern and an upper capping layer pattern, and the lower capping layer pattern has a smaller width than the upper capping layer; and
a spacer covering a sidewall of the gate pattern.

19. The MOS transistor according to claim 18, wherein and the lower capping layer pattern has a smaller width than the gate electrode.

20. The MOS transistor according to claim 18, further comprising an outer spacer covering the spacer, wherein the spacer comprises an oxide layer and the outer spacer comprises a silicon nitride layer.

21. The MOS transistor according to claim 18, further comprising:
semiconductor layers disposed at both sides of a channel region disposed under the gate pattern.

22. The MOS transistor according to claim 21, wherein the semiconductor layers comprise a semiconductor material to apply stress to a channel region disposed under the gate pattern, wherein the semiconductor layers comprise a semiconductor material containing Ge or carbon (C).

23. The MOS transistor according to claim 21, further comprising:
source and drain regions disposed in the semiconductor layers,
wherein the source and drain regions extend from the semiconductor layer to the semiconductor substrate.
